(19) United States
(12) Patent Application Publication
(10) Pub. No.: US 2006/0252249 A1
(43) Pub. Date: Nov. 9, 2006

(54) Solder ball pad surface finish structure of circuit board and fabrication method thereof

(76) Inventors: Shih-Ping Hsu, Hsin-chu (TW); Sao-Hsia Tang, Hsin-shu (TW); Ying-Tung Wang, Hsin-chu (TW); Wen-Hung Hu, Hsin-chu (TW); Chao-Wen Shih, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/429,766

(22) Filed: May 8, 2006

(30) Foreign Application Priority Data
May 9, 2005 (TW) 094114848

(51) Int. Cl. H01L 21/44

(52) U.S. Cl. 438/614

(57) ABSTRACT

A solder ball pad surface finish structure of a circuit board and a method for fabricating the same are proposed. An insulative protecting layer with a plurality of openings is formed on a circuit board to expose solder ball pads on the circuit board. A conductive layer is formed on the insulative protecting layer and in the openings, and a resist layer is also formed thereon. A plurality of openings are formed and defined in the resist layer corresponding to the solder ball pads. The area of openings of resist layer can be larger or smaller than the area of the openings of insulative protecting layer, and the resist layer is hung above the solder ball pads. A metal layer is formed on the conductive layer and in the openings of resist layer by electroplating and an adhesive layer is formed successively. Then, the resist layer and the conductive layer underneath the resist layer are removed. Afterwards, the adhesive layer is further processed by re-flow process.

### CROSS-REFERENCE TO RELATED APPLICATION

This application claims benefit under 35 USC 119 of Taiwan Application No. 094113848, filed May 9, 2005.

### FIELD OF THE INVENTION

The present invention relates to solder ball pad surface finish structures of circuit boards and a fabrication method thereof, and more particularly, to a solder ball pad surface finish structure of circuit board, which is electrically, connect with outside and a fabrication method thereof.

### BACKGROUND OF THE INVENTION

Currently, semiconductor packaging can be generally divided into two types: wire bonding and flip-chip type of package. In wire bonding type of package, a semiconductor chip is electronically connected to the circuit board via bonding wires. In flip chip type of package, a semiconductor chip has its active surface facing down to be mounted on the circuit board, and is electrically connected to the circuit board via a plurality of bumps. Since boning wires which occupy a much larger space is not used in flip chip type of package to electronically connect the semiconductor chip to the circuit board, the overall package can be smaller in size and lighter in weight. Regardless of wire bonding or flip chip type of packages, a process is required to form a plurality of solder balls in a ball grid array on the bottom of the circuit board during packaging, so as to form electrical connections between the circuit board and an external device. The specifications described below is based on a flip-chip type of package, however it should be noted that in practice that a plurality of solder balls are required to be mounted on the bottom surface of the circuit board in each various BGA package.

FIG. 1 is a flip-chip structure wherein a plurality of solder balls 12 are formed on the bottom surface of the semiconductor chip 11, and the semiconductor chip 11 is electrically connected to corresponding location of a circuit board 13 via the solder balls 12. Bottom filling materials 14 are used between the semiconductor chip 11 and the circuit board 13 in order to bond the semiconductor chip 11 and the circuit board 13 firmly.

In addition, after completing the process of attaching the semiconductor chip to the circuit board, in order to allow the circuit board 13 to be electronically connected to an external electronic device, a plurality of solder balls must be implanted on a bottom side of the circuit board 13. In order to allow the solder balls 15 to be firmly implanted on the circuit board 13, a solder material must be applied in advance on the solder ball pads 16 for the solder ball to be attached thereon.

The common fabricating method for forming solder materials on the solder ball pads of the circuit board is molding technology, which involves firstly forming an insulative protective layer with openings on a circuit board, allowing a plurality of solder ball pads to be exposed and then a molding board having a plurality of openings is placed on the insulative protective layer of the circuit board, so as to form solder bumps on the solder ball pads via those openings. This can be achieved by rolling or spraying methods to deposit solder materials through the openings. After the solder materials are deposited, the molding board can be removed. Subsequently a re-flow process is performed to form the solder balls on the solder ball pads.

Referring to FIGS. 2A and 2B (PRIOR ART), schematic partial views showing the formation of solder materials on the solder ball pads of a conventional circuit board in which 90 degree angle C is formed between the solder ball pad 22 and an opening 21a of the insulative protective layer. As such, when the solder material is deposited in the opening of the insulative protecting layer, the 90°angle C prevents the solder material to be deposited at the corner angle. Besides, during re-flow process of the solder material, due to the bonding and surface tension of the characteristics of molecules, the 90°angle C cannot be completely, forming a gap (s), as shown in FIG. 2B, between the solder structure 25 and the insulative protecting layer 21. This may leads to detachment of the solder structure 25 and therefore reduction in reliability in the latter procedures.

In addition, since the corner formed by the solder ball pad and the opening of the insulating protection layer cannot be completely filled by the solder material, the contact area between the solder material and the solder ball is reduced accordingly, as a result, it is harder to make the solder material that forms the solder structure to be adhered on the solder ball pad, thereby seriously affecting the quality of solder balls and the electrical connections.

Thus, in view of the foregoing problems of prior art, there exists an urgent need to provide a solution to the prior art problems such as difficulty in solder material deposition, gap formation between the solder structure and the insulative protecting layer, inability to improve the quality of solder structure and electrical connections for the circuit board.

### SUMMARY OF THE INVENTION

In the view of drawbacks of conventional technologies, a primary objective of the present invention is to provide a solder ball pad surface finish structure of a circuit board and fabrication methods thereof, which involves forming a surface indented structure on the centre of the solder ball pad of the circuit board, to allow the solder material to be effectively applied thereon, so as to avoid the prior art problems such as difficulty in solder material deposition, gap formation between the solder structure and the insulative protecting layer.

Another objective of the invention is to provide a solder ball pad surface finish structure of a circuit board and fabrication methods thereof, for improving the reliability of fabrication.

In order to achieve the foregoing and other objectives, the fabricating method of a solder ball pad surface finish structure of a circuit board provided by the present invention, comprising: providing a circuit board having solder ball pads on at least one surface and a insulative protecting layer with openings on the circuit board for exposing the solder ball pads; forming a conductive layer on the insulative protecting layer and the opening thereof, and applying a resist layer on the conductive layer with openings which is larger than the openings of the insulative protecting layer at the positions corresponding to the solder ball pads; performing electroplating process to form a metal layer and an adhesive layer successively on the conductive layer in the openings of the resist layer; and removing the resist and the conductive layer applied thereof, followed by a re-flow process on the adhesive layer on the top of the metal layer to form a centre surface indented solder ball pad surface finish structure.

Since the openings of the resist layer are larger in size than the openings of the insulative protecting layer, the solder ball pad and a conductive layer of a insulative protecting layer around the solder ball correspondingly are exposed in the opening of the resist layer, result in a metal layer and an adhesive layer are formed on the conductive layer by electroplating, so that the solder ball pad surface finish structure formed protrude in the opening of the insulative protecting layer, so as to form bowl-shaped solder ball pad surface finish structure.

Furthermore, the size of openings of resist layer can be smaller than the size of the openings of insulative protecting layer, allowing the resist layer to be suspended above the solder ball pads correspondingly, and allowing the metal layer and the adhesive layer to cover the sidewall of the opening of the insulative protecting layer and the solder bal pads, so as to form bowl-shaped solder ball pad surface finish structure.

Moreover, the size of openings of resist layer can be larger or smaller than the size of the openings of insulative protecting layer, allowing the resist layer to cover the conductive layer of the central part of the solder ball pads, to form a hollow structure on the metal layer and the adhesive layer formed in the openings o the resist layer, thereby forming a bowl-shaped solder ball pad surface finish structure.

Through the foregoing fabricating method, a solder ball pad surface finish structure of the circuit board disclosed by the present invention, is formed by forming solder ball pads and insulative protecting layer with openings for exposing the solder ball pads formed underneath on the surface of the circuit board. The solder ball pad surface finish structure formed on the solder ball pad of the circuit board, comprises: a metal layer and an adhesive layer. The adhesive layer covers the exposed surface of the metal layer to form a central surface indented solder ball pad surface finish structure on the solder ball pad. A conductive layer is formed between the metal layer and the solder ball pad.

Accordingly, the fabricating method of the solder ball pad surface finish structure of the circuit board of the invention involves forming a central surface indented solder ball pad surface finish structure 34, so that in the latter procedure, this indented solder ball pad surface finish structure provides a bowl shaped attachment surface to allow the conductive element such as solder material to be firmly attached thereon, thereby enhancing the fabricating reliability.

Besides, in the fabricating method of the solder ball pad surface finish structure of the circuit board of the invention, electroplating metal layer and adhesive layer on the surface of the solder ball pad in advance prevents the conventional problem of reduced contact surface area between the solder material and the solder ball pad resulting from that the corner formed between the solder ball pad and the insulative protecting layer cannot be fully filled by the solder material in the prior art where solder material is directly deposited on the solder ball pad. The surface indented solder ball pad surface finish structure can provide much smoother surface to allow the solder material to be firmly attached on the solder ball pad. This provides greater bonding force between the solder material and the solder ball pad, with increased fabricating reliability.

### BRIEF DESCRIPTION OF THE DRAWINGS

FIG. 1. (PRIOR ART) is a schematic cross-sectional view of a conventional flip chip type of package;

FIGS. 2A and 2B (PRIOR ART) are schematic cross-sectional views showing the conventional method of forming solder material on solder ball pads of a circuit board;

FIGS. 3A-3G are schematic cross-sectional views showing the fabricating method of solder ball pad surface finish structure of a circuit board of a first preferred embodiment of the invention;

FIGS. 4A-4E are schematic cross-sectional views showing the fabricating method of solder ball pad surface finish structure of a circuit board of a second preferred embodiment of the invention; and

FIGS. 5A-5D are schematic cross-sectional views showing the fabricating method of solder ball pad surface finish structure of a circuit board of a third preferred embodiment of the invention.

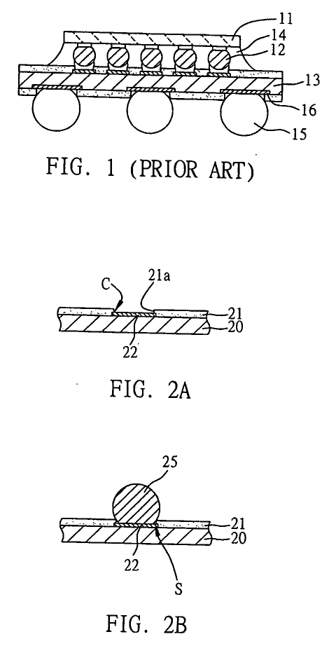

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

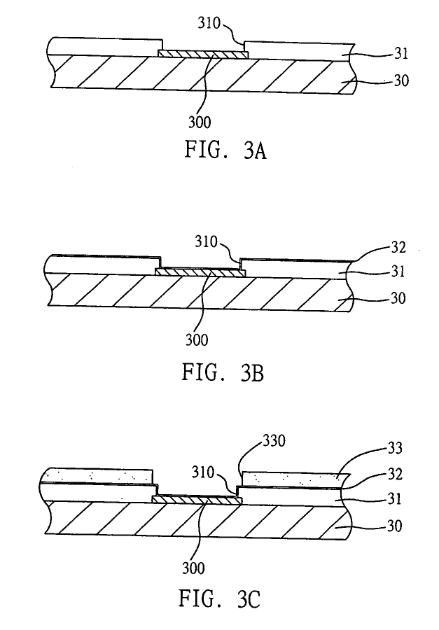

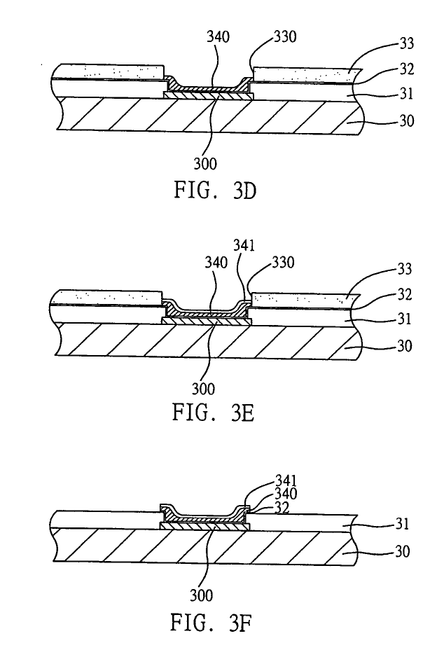

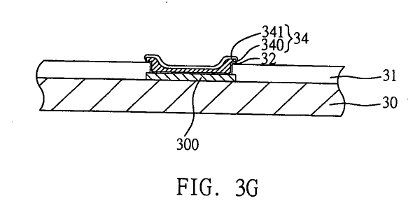

Referring to FIGS. 3A-3G, schematic cross-sectional views showing the fabricating method of the solder ball pad surface finish structure of the circuit board of the first preferred embodiment of the invention are provided. It should be noted that the drawings are all simplified schematic views, only to show the basic architecture of the invention. The number shape and size of each components shown in the drawings are not drawn in scale, and only shows one of the possible arrangements in practice. The number, shape and size of the components may be much more complicated in practice.

The sectional schematic diagrams of a solder ball pad surface finish structure of circuit board and a fabrication method thereof of the first preferred embodiment of the present invention are illustrated in FIG. 3A to 3B respectively. To be noticed here, the drawings are simplified diagrams to illustrate the basic structure of the present invention, therefore the relative structures of drawings shown are different in quantity, shape, and size with real case, however the quantity, shape, and size of real case is design of selection, and the layout of modality should be more complicate.

Referring to FIG. 3A, a circuit board with a plurality of solder ball pads 300 formed on at least one surface thereof is provided. The circuit board 30 shown in here is a simplified version, and can be a double layer or multilayer circuit board, which has the circuit layout, completed. Solder ball pads 300 are electrically connected to the inner circuits via conductive vias (not shown) for the conductive layer and solder balls to be formed thereon in latter procedures. There are numerous fabricating technologies for forming circuit layout and solder ball pads. However they are well known in the art and are not the main focus in the present invention, therefore detailed descriptions are not given in here.

The surface of the circuit board 30 is formed with an insulative protecting layer 31 which is formed by either printing, spinning coating, or laminating methods to be applied on the surface of the circuit board, followed by a patterning procedure to allow the solder ball pads 300 to be exposed to the insulative protecting layer 31. The insulative protecting layer 31 can be made of a solder resist material such as green paint, and through a series of processes including exposure and development, the insulative protecting layer 31 is patterned to form openings 310 for exposing the solder ball pads 300.

Referring to FIG. 3B, a conductive layer 32 is formed on the insulative protecting layer 31 and openings 310. The conductive layer 32 acts as a conductive path for the electrons current to pass through required for the electroplating metal in a subsequent electroplating process, which is formed by metal, alloys or several deposited metal layers or conductive polymer.

Referring to FIG. 3C, a resist layer 33 is subsequently formed and then patterned on the conductive layer 32. The resist layer 33 can be a photoresist layer formed by a photoresist material in a form of a dry film or in liquid form, and then through exposure and development processes the resist layer 33 is patterned to form openings 330 on the resist layer 33. The openings 330 are formed at the positions corresponding to the solder ball pads and are larger than the openings 310 of the insulative protecting layer 31, allowing the conductive layer 32 around the positions where solder ball pads 300 are formed to be exposed.

Referring to FIG. 3D, an electroplating process is performed on the circuit board, where a metal layer 340 is formed on the conductive layer 32 exposing from the openings 330 of the resist layer 33. The conductive layer 32 acts as the electrical conductive path. The metal layer 340 is protruded from the openings of the insulative protecting layers 31 to cover the solder ball pads 300 and part of the insulative protecting layer 31 around the solder ball pads 300, in such a way that the metal layer 340 is surface indented at the centre corresponding to the positions of the solder ball pad 300. The metal layer 340 can be made of one of the metal: copper, nickel, gold, silver, tin or the alloys thereof. However, in practice, since copper has been more widely used as a plating material and is cheaper, therefore the metal layer 340 is preferably made of platting copper in practice, but is not limited to copper.

Referring to FIG. 3E, electroplating process is continued to form an adhesive layer 341 on the metal layer 340 using the metal layer 32 as the conductive path for the electrons current. Since the metal layer 340 is surface indented at the centre at the positions corresponding to the positions of solder ball pads 300, the adhesive layer 341 is also surface indented at the centre at the positions corresponding to solder ball pads 300. The material of the adhesive layer 341 can be selected from a metal including lead, tin, silver, copper, gold, bismuth, and antimony or the alloys thereof.

Referring to FIG. 3F, the resist layer 33 and the conductive layer 32 underneath are removed.

Referring to FIG. 3G, the adhesive layer 341 is re-flowed to allow the adhesive layer 341 to cover the exposed surface of the metal layer 340, so as to form a surface indented solder ball pad surface finish structure 34 at the centre on the solder ball pad 300.

Besides, a conductive material such as solder material (not shown) can be attached to the solder ball pad surface finish structure 34 to form electrical connections between the circuit board and external electronic devices.

Accordingly, the fabricating method of the solder ball pad surface finish structure of the circuit board of the invention involves forming a central surface indented solder ball pad surface finish structure 34, so that in the latter procedure, this indented solder ball pad surface finish structure provides a bowl shaped attachment surface to allow the conductive element such as solder material to be firmly attached thereon, thereby enhancing the fabricating reliability.

Besides, in the fabricating method of the solder ball pad surface finish structure of the circuit board of the invention, electroplating metal layer and adhesive layer on the surface of the solder ball pad in advance prevents the conventional problem of reduced contact surface area between the solder material and the solder ball pad resulting from that the corner formed between the solder ball pad and the insulative protecting layer cannot be fully filled by the solder material in the prior art where solder material is directly deposited on the solder ball pad. The surface indented solder ball pad surface finish structure can provide much smoother surface to allow the solder material to be firmly attached on the solder ball pad. This provides greater bonding force between the solder material and the solder ball pad, with increased fabricating reliability.

Through the foregoing fabricating method, a solder ball pad surface finish structure of the circuit board disclosed by the present invention, is formed by forming solder ball pads 300 and insulative protecting layer 31 with openings 310 for exposing the solder ball pads 300 formed underneath on the surface of the circuit board. The solder ball pad surface finish structure 34 formed on the solder ball pad 300 of the circuit board 30, comprises: a metal layer 340 protruding the opening 310 of the insulative protecting layer 310, and is surface indented at the centre at the positions corresponding to the solder ball pads 300; an adhesive layer 341 covering the exposed surface of the metal layer 340 to form a surface indented solder ball pad surface finish structure on the solder ball pad 300. A conductive layer 32 is formed between the metal layer 340 and the solder ball pad 300.

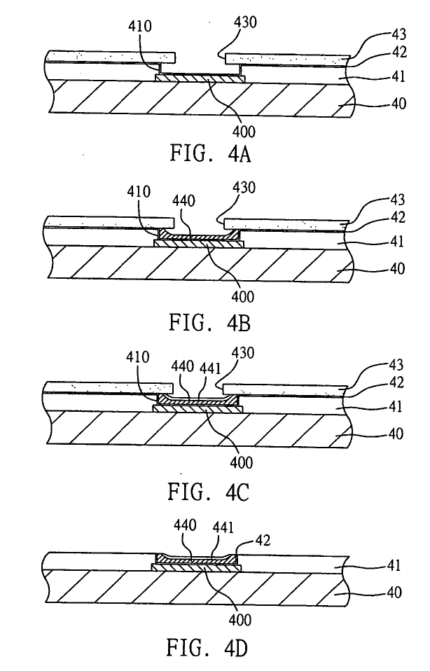

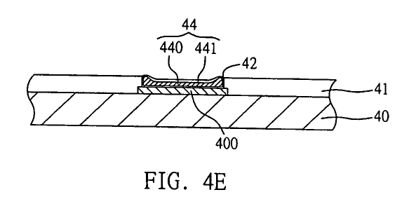

Referring to FIGS. 4A-4E, schematic cross-sectional views of the solder ball pad surface finish structure of the circuit board of the second preferred embodiment of the invention are shown. The fabricating method of this embodiment is almost the same as that of the fist preferred embodiment, with the only major difference being that the size of the opening of the resist layer is smaller than the opening of the insulative protective layer.

Referring to FIG. 4A, a circuit board with a plurality of solder ball pads 400 formed on at least one surface thereof is provided, which is formed with a insulative protecting layer 41 with openings 410 for exposing the solder ball pads 400; a conductive layer 42 is formed on the insulative protecting layer 41 and the openings 410; followed by forming a resist layer 43 on the conductive layer 42 with openings being formed by exposure and development processes at the positions corresponding to the solder ball pads 400 and the size of the openings 430 is smaller than the openings 410 of the insulative protecting layer, allowing a part of the resist layer 43 to be suspended above the solder ball pads 400.

Referring to FIG. 4B, an electroplating process is performed on the circuit board, where a metal layer 440 is deposited on the conductive layer 42 on the solder ball pads 400 and the sidewalls of the openings 410 of the insulative protecting layer. The conductive layer 42 acts as the conductive path for the electrons current. The metal layer 440 can be made of one of the metal: copper, nickel, gold, silver, tin or the alloys thereof.

Referring to FIG. 4C, electroplating process is continued to form an adhesive layer 441 on the metal layer 440 using the metal layer 42 as the conductive path for the electrons current. The material of the adhesive layer 341 can be selected from a metal including lead, tin, silver, copper, gold, bismuth, and antimony or the alloys thereof.

Referring to FIG. 4D, the resist layer 43 and the conductive layer 43 underneath are removed.

Referring to FIG. 4E, the adhesive layer 441 is re-flowed to allow the adhesive layer 441 to cover the exposed surface of the metal layer 440, so as to form a surface indented solder ball pad surface finish structure 44 at the centre on the solder ball pad 400.

Through the foregoing fabricating method, a solder ball pad surface finish structure of the circuit board disclosed by the present invention, is formed by forming solder ball pads 400 and insulative protecting layer 41 with openings 410 for exposing the solder ball pads 400 formed underneath on the surface of the circuit board. The solder ball pad surface finish structure 44 formed on the solder ball pad 400 of the circuit board 40 comprises a metal layer 440 protruding the opening 410 of the insulative protecting layer 410, and is surface indented at the centre at the positions corresponding to the solder ball pads 400; an adhesive layer 441 covering the exposed surface of the metal layer 440 to form a surface indented solder ball pad surface finish structure on the solder ball pad 400. A conductive layer 42 is formed between the metal layer 440 and the solder ball pad 400.

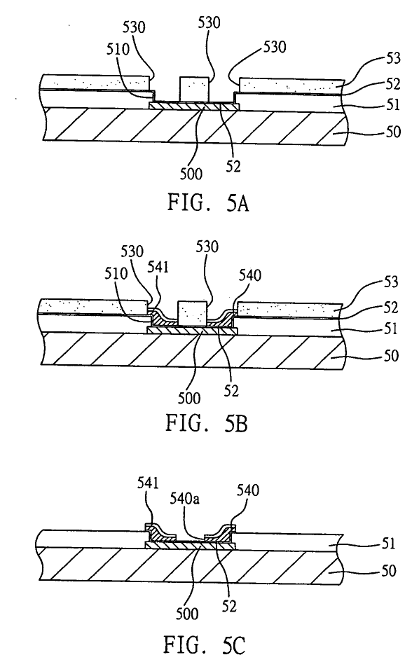

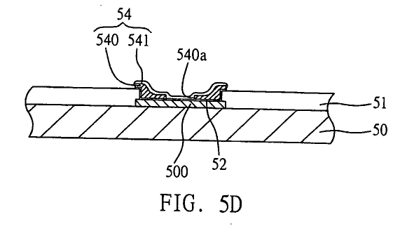

Referring to FIGS. 5A-5D, schematic cross-sectional views of the solder ball pad surface finish structure of the circuit board of the third preferred embodiment of the invention are shown. The fabricating method of this embodiment is almost the same as that of the third preferred embodiment. The only major difference is that in this embodiment, a resist layer is formed at the centre of the solder ball pad of the circuit board, allowing a metal layer with a hollow structure to be formed on the solder ball pad in the opening of the resist layer, and a central surface indented adhesive layer to be formed on the metal layer and the solder ball pad.

Referring to FIG. 5A, a circuit board with a plurality of solder ball pads 500 formed on at least one surface thereof is provided, which is formed with an insulative protecting layer 51 with openings 510 for exposing the solder ball pads 500; a conductive layer 52 is formed on the insulative protecting layer 51 and the openings 510; followed by forming a resist layer 53 on the conductive layer 52 with openings 530 that is larger than the openings 510 of the insulative protecting layer. The openings 530 of the resist layer 53 are formed around the periphery of the solder ball pads 500, allowing the resist layer 53 covering the centre part o the solder ball pad 500.

Referring to FIG. 5B, an electroplating process is performed on the circuit board 50, where a metal layer 540 and an adhesive layer 541 are subsequently formed on the conductive layer 52 in the openings 530 of the resist layer using the conductive layer 52 acts as the conductive path for the electrons current. The metal layer 540 protrudes the openings 510 of the insulative protecting layers 51 to cover part of the insulative protecting layer 51, and the surface of the metal layer 540 and the adhesive layer 541 are indented at the centre. The metal layer 540 can be made of one of the metal: copper, nickel, gold, silver, tin or the alloys thereof. The material of the adhesive layer 541 can be selected from a metal including lead, tin, silver, copper, gold, bismuth, and antimony or the alloys thereof.

Referring to FIG. 5C, the resist layer 53 and the conductive layer 53 underneath are removed to form the metal layer 540 with a central hollow structure 540a and the adhesive layer 541.

Referring to FIG. 5D, the adhesive layer 541 is re-flowed to allow the adhesive layer 541 to cover the exposed surface of the metal layer 540, so as to form a central surface indented solder ball pad surface finish structure 54 on the solder ball pad 500 of the circuit board.

Through the foregoing fabricating method, a solder ball pad surface finish structure of the circuit board disclosed by the present invention, is formed by forming solder ball pads 500 and insulative protecting layer 51 with openings 510 for exposing the solder ball pads 500 formed underneath on the surface of the circuit board. The solder ball pad surface finish structure 54 formed on the solder ball pad 500 of the circuit board 50 comprises a metal layer 540 having a hollow structure 540a, wherein the metal layer 540 is protruded from the opening 510 of the insulative protecting layer; an adhesive layer 541 covering the exposed surface of the metal layer 540 and filling in the hollow structure 540a to form a surface indented solder ball pad surface finish structure on the solder ball pad 500. A conductive layer 52 is formed between the metal layer 540 and the solder ball pad 500.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A fabricating method of a solder ball pad surface finish structure of circuit board, comprising:
preparing a circuit board having solder ball pads on at least one surface therof and forming an insulative protecting layer with openings for exposing the solder ball pads;
forming a conductive layer on the insulative protecting layer and the surface of the openings;
forming a resist layer on the conductive layer, with openings being formed in the resist layer at the positions corresponding to the solder ball pads and the openings of the resist layer is lager than the openings of the insulative protecting layer allowing the conductive layer at the positions corresponding to the solder ball pads and the insulative protecting layer surrounding the solder ball pads;
performing an electroplating process to successively form a metal layer and an adhesive layer on the conductive layer in the openings of the resist layer;
removing the resist layer and the conductive layer underneath; and
performing a re-flow process to allow the adhesive layer to cover the exposed surface of the metal layer so as to form a central surface indented solder ball pad surface finish structure on the solder ball pad of the circuit board.

2. The fabricating method of the solder ball pad surface finish structure of the circuit board of claim 1, further comprises implanting conductive elements on the solder ball pad surface finish structure for forming electrical connections between the circuit board and external electronic devices.

3. The fabricating method of the solder ball pad surface finish structure of the circuit board of claim 1, wherein the metal layer is made of a material selected from a group consisting of copper, nickel, gold, silver, and tin.

4. The fabricating method of the solder ball pad surface finish structure of the circuit board of claim 1, wherein the adhesive layer is made of a material selected from a group consisting of lead, tin, silver, copper, gold, bismuth, and antimony or the alloys thereof.

5. The fabricating method of a solder ball pad surface finish structure of the circuit board, comprising:
preparing a circuit board having solder ball pads on at least one surface thereof and forming an insulative protecting layer with openings for exposing the solder ball pads;
forming a conductive layer on the insulative protecting layer and the surface of the openings;
forming a resist layer on the conductive layer, with openings being formed in the resist layer at the positions corresponding to the solder ball pads and the openings of the resist layer is smaller than the openings of the insulative protecting layer allowing part of the resist layer to be suspended above the solder ball pads, for exposing the conductive layer at the positions corresponding to the solder ball pads and the sidewall of the openings of the insulative protecting layer;
performing an electroplating process to successively form a metal layer and an adhesive layer on the conductive layer in the openings of the resist layer;
removing the resist layer and the conductive layer underneath; and
performing a re-flow process to allow the adhesive layer to cover the exposed surface of the metal layer so as to form a central surface indented solder ball pad surface finish structure on the solder ball pad of the circuit board.

6. The fabricating method of the solder ball pad surface finish structure of the circuit board of claim 5, further comprises implanting conductive elements on the solder ball pad surface finish structure for forming electrical connections between the circuit board and external electronic devices.

7. The fabricating method of the solder ball pad surface finish structure of the circuit board of claim 5, wherein the metal layer is made of a material selected from a group consisting of copper, nickel, gold, silver, and tin.

8. The fabricating method of the solder ball pad surface finish structure of the circuit board of claim 5, wherein the adhesive layer is made of a material selected from a group consisting of lead, tin, silver, copper, gold, bismuth, and antimony or the alloys thereof.

9. A fabricating method of a solder ball pad surface finish structure of circuit board, comprising:
preparing a circuit board having solder ball pads on at least one surface thereof and forming an insulative protecting layer with openings for exposing the solder ball pads;
forming a conductive layer on the insulative protecting layer and the surface of the openings;
forming a resist layer on the conductive layer, with openings that are larger in size that the openings of the insulative protecting layer being formed in the resist layer at the positions corresponding to the surrounding areas of the solder ball pads allowing the central part of the solder ball pad to be covered by the resist layer;
performing an electroplating process to successively form a metal layer with a hollow central part and an adhesive layer on the conductive layer in the openings of the resist layer;
removing the resist layer and the conductive layer underneath; and
performing a re-flow process to allow the adhesive layer to cover the exposed surface of the metal layer and fill in the hollow structure of the metal layer, so as to form a central surface indented solder ball pad surface finish structure on the solder ball pad of the circuit board.

10. The fabricating method of the solder ball pad surface finish structure of the circuit board of claim 9, further comprises implanting conductive elements on the solder ball pad surface finish structure for forming electrical connections between the circuit board and external electronic devices.

11. The fabricating method of the solder ball pad surface finish structure of the circuit board of claim 9, wherein the metal layer is made of a material selected from a group consisting of copper, nickel, gold, silver, and tin.

12. The fabricating method of the solder ball pad surface finish structure of the circuit board of claim 9, wherein the adhesive layer is made of a material selected from a group consisting of lead, tin, silver, copper, gold, bismuth, and antimony or the alloys thereof.

13. A solder ball pad surface finish structure of the circuit board, in which the circuit board is formed with solder ball pads and insulative protecting layer with openings in the insulative protecting layer for exposing the solder ball pads, and the solder ball pad surface finish structure is formed on the solder ball pads, comprising:
a metal layer which has a indented surface at the centre; and
an adhesive layer, formed on the metal layer for covering the exposed surface of the metal layer.

14. The solder ball pad surface finish structure of the circuit board of claim 13, wherein the solder ball pad surface finish structure is protruded from the openings of the insulative protecting layer allowing part of the insulative protecting layer surrounding the solder ball pads to be covered.

15. The solder ball pad surface finish structure of the circuit board of claim 13, wherein the solder ball pad surface finish structure is not protruded from the openings of the insulative protecting layer, allowing the sidewall of the insulative protecting layer to be covered by the surrounding part of the metal layer to make the metal layer indented at the centre.

16. The solder ball pad surface finish structure of the circuit board of claim 13, wherein a conductive layer is formed between the metal layer and the solder ball pads.

17. The solder ball pad surface finish structure of the circuit board of claim 13, wherein the metal layer is made of a material selected from a group consisting of copper, nickel, gold, silver, and tin.

18. The fabricating method of the solder ball pad surface finish structure of the circuit board of claim 1, wherein the adhesive layer is made of a material selected from a group consisting of lead, tin, silver, copper, gold, bismuth, and antimony or the alloys thereof.

19. A solder ball pad surface finish structure of the circuit board, in which the circuit board is formed with solder ball pads and insulative protecting layer with openings in the insulative protecting layer for exposing the solder ball pads, and the solder ball pad surface finish structure is formed on the solder ball pads, comprising:
a metal layer formed on the solder ball pad with a central hollow structure; and
an adhesive layer, covering the exposed surface of the metal layer and filling in the hollow structure, to form a central surface indented solder ball pad surface finish structure on the solder ball pads of the circuit board.

20. The solder ball pad surface finish structure of the circuit board of claim 19, wherein a conductive layer is formed between the metal layer and the solder ball pads.

21. The solder ball pad surface finish structure of the circuit board of claim 19, wherein the solder ball pad surface finish structure is protruded from the openings of the insulative protecting layer and covering part of the insulative protecting layer surrounding the corresponding solder ball pads.

22. The solder ball pad surface finish structure of the circuit board of claim 19, wherein the metal layer is made of a material selected from a group consisting of copper, nickel, gold, silver, and tin.

23. The solder ball pad surface finish structure of the circuit board of claim 19, wherein the adhesive layer is made of a material selected from a group consisting of lead, tin, silver, copper, gold, bismuth, and antimony or the alloys thereof.
